(19) United States
(12) Patent Application Publication
(10) Pub. No.: US 2007/0251574 A1
(43) Pub. Date: Nov. 1, 2007

(54) Dye-sensitized solar cell

(75) Inventors: Hirokazu Fujimaki, Tokyo (JP); Minoru Watanabe, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO. LTD., Tokyo (JP)

(21) Appl. No.: 11/729,873

(22) Filed: Mar. 30, 2007

(30) Foreign Application Priority Data
Apr. 28, 2006 (JP) 2006-124652

(51) Int. Cl. H01L 31/00

(52) U.S. Cl. 136/263

(57) ABSTRACT

In a dye-sensitized solar cell comprising a first electrode having a photoelectric conversion layer, a second electrode disposed so as to oppose the first electrode, and electrolyte filled at least in between the first electrode and second electrode, the first electrode is constructed with a plurality of first electrode layers disposed superposed in a direction that opposes to the second electrode.

### CROSS REFERENCE TO RELATED APPLICATION

This application claims the priority of Application No. 2006-124652, filed Apr. 28, 2006 in Japan, the subject matter of which is incorporated herein by reference.

### TECHNICAL FIELD OF THE INVENTION

The present invention relates to a dye-sensitized solar cell. In particular, it relates to an improvement in a cell structure that principally involves an electrode structure of a dye-sensitized solar cell.

### BACKGROUND OF THE INVENTION

The energy of sunlight shining down on the entire earth is said to be 100 thousand times the power consumption of the entire world. Without performing any special industrial activities, we are already surrounded by a vast energy resource. A solar cell is a device for converting this energy resource (sunlight) into electrical energy that can be easily used by humans, and it has a history of fifty years.

Of the solar cells that are currently manufactured, 90% or more are silicon (Si) solar cells. Silicon solar cells fall into forms of monocrystal Si, polycrystal Si, and amorphous Si. These forms have different conversion efficiency, production cost and processability, and they are selected according to the product on which the solar cell is mounted, their purpose, and the installation site. Among Si solar cells, a monocrystal Si solar cell has the highest conversion efficiency, and a monocrystal Si solar cell product that has been developed to reach 20% of the practical level is being manufactured. Moreover, for special purposes such as applications to artificial satellites, a compound semiconductor having ultra high conversion efficiency and superior anti radiation deterioration properties is used in some cases.

Incidentally, renewable energy such as with solar cells is said to be an ideal energy resource with practically no environmental load. However, broad use of this energy resource has not advanced up until now. One of the major reasons for this is that the cost of power generation is high. In order to further activate markets and realize an energy supply system (society) that is in harmony with nature under such circumstances, the cost of power generation needs to be reduced. To achieve this, technological advancement is essential, and specifically this is being approached from two directions.

The first approach is to realize higher conversion efficiency of the solar cell itself. If power generation efficiency is doubled for the same production cost, the production cost will be halved. The second approach is a method of reducing the unit price of a product by improving the materials, the production method, or the structure itself. Currently, main stream Si solar cells require a high purity Si material, and in addition, the production step requires high temperature and high vacuum. In generating or processing Si materials for a large area substrate, it is difficult to effectively reduce the production cost due to an increase in the size of the production facilities and so forth. Therefore, various kinds of solar cells that use materials other than Si materials to reduce material cost, and that furthermore reduce energy consumption in the production process to significantly reduce the total cost, by removing the high temperature step and the vacuum step as much as possible, have been proposed. A typical example of this is a dye-sensitized type (Graetzel cell) solar cell, and a dry type organic thin film solar cell.

A dye-sensitized type solar cell has a simple structure, and construction material thereof can be selected from bountiful resources. Furthermore, the dye-sensitized type solar cell is estimated to reduce power generation cost to one-fifth or less of that of the currently prevailing Si solar cell, because the energy consumption in the production steps is low, and large facilities are not required.

Hereinafter, a manufacturing method for a general dye-sensitized solar cell is described. First, a glass substrate, the top surface of which has been coated with a conductive coating of FTO or ITO is prepared. Next, a paste material containing TiO₂ particles is coated by a screen printing method or a coating method.

Next, this titanium dioxide paste material is sintered by an annealing process. As a result, organic material which is the paste solvent, is spattered, and the fine titanium dioxide particles neck, forming diffusion passages for electrons.

Next, the substrate that has been subjected to this sintering process is immersed in an alcohol solution containing Ru metal complex (representative example: N719) for approximately half a day to have Ru metal complex dyes adsorbed on the surface of this TiO₂ of a porous structure. Furthermore, after cleaning with ethanol, the substrate is allowed to dry in a dark place.

Next, a thin Pt conductive coating is sputtered on the glass substrate in which a pin hole is formed, as a counter pole, and Haimiran film (Mitsui DuPont Chemical Co. Ltd.) is formed around this counter pole and the above TiO₂ electrode plate, and then both of the poles are bonded.

Subsequently, after injecting electrolyte containing iodine through the pin hole mentioned above, and filling the gap between both of the poles with the electrolyte, the pin hole is sealed.

After that, negative electrode wiring is connected to the titanium dioxide pole, and positive electrode wiring is connected to the counter pole side, and a flat plate shaped dye-sensitized solar cell is thereby constructed.

In this solar cell, light is inputted from the side on which the titanium dioxide is formed, and the light is absorbed by the dye adsorbed on the titanium dioxide surface to excite electrons. Since the energy ranking of the conducting zone of titanium dioxide at approximately 0.2 eV is low compared to the ranking for dye excitation, these excited electrons migrate to the titanium dioxide side. Furthermore, these electrons migrate through a conductive coating on the glass to operate an external load, and then reach the positive electrode side. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

According to the manufacturing method and mechanism described above, it has become possible to manufacture an inexpensive solar cell having a high level of conversion efficiency. Since abundant resources under normal pressure and at low temperature can be used, it is possible to manufacture an extremely inexpensive solar cell compared to silicon solar cells.

However, there is a problem in that even the top data of current photoelectric conversion rates is only approximately 12%, and this conversion efficiency becomes half or less for a large area cell at a practical level. The principal reason for this efficiency reduction is energy loss caused by internal resistance of the transparent conductive coating on the glass substrate. In other words, it is difficult to form a conductive coating having sufficiently low resistance, without interfering with transparency.

Moreover, a film type dye-sensitized solar cell that features lower price, thinner coating, lighter weight, and even colorfulness from a selection of dyes, has drawn considerable attention. However, in this film type dye-sensitized solar cell, especially the sheet resistance (10 to 20 K/□) of the transparent conductive coating becomes higher than that on the glass substrate. As a result, efficiency when increasing the cell area is more significantly reduced.

As described above, to bring the dye-sensitized solar cell into practical use, there is an important challenge of suppressing the increase in internal resistance due to the increased cell area. A certain level of improvement in efficiency is possible if a bus bar electrode or a finger electrode is applied, however even with this an efficiency reduction of 20 to 30% occurs, and there is an influence on conversion efficiency due to the increased cost and the reduction in numerical aperture, hindering the advantage of a low cost solar cell.

Here a scheme for thickening the transparent conductive coating may be considered. However, in this case, there are problems such as a reduction in light transmittance and the occurrence of cracking due to stress, and therefore this still has problems as a fundamental solution.

Moreover, a method of dividing inside the cell into a stripe shape or the like, and forming a metallic pattern in the immediate vicinity, has been employed. However in this method, in addition to cost increase, there is a problem of a reduction in the effective area (numerical aperture) that contributes to photoelectric conversion.

Furthermore, in a plastic type dye-sensitized solar cell, the sintering temperature of titanium dioxide cannot be raised to the temperature of the glass substrate. Therefore necking between the titanium dioxide particles becomes insufficient, and the internal resistance is increased.

Here, in an invention disclosed in Patent Document 1, a metallic wire body or a metallic mesh body (tungsten of the like) coated with a semiconductor layer, is used as an electrode of a dye-sensitized solar cell.

Moreover, Patent Documents 2 and 3 disclose inventions that provide a solar cell having a broad light absorption wavelength range in which different dyes are adsorbed on a porous semiconductor layer of a dye-sensitized solar cell.

[Patent Document 1] Japanese Unexamined Patent Publication No. 2005-196982

[Patent Document 2] Japanese Unexamined Patent Publication No. 2003-249274

[Patent Document 3] Japanese Unexamined Patent Publication No. 2000-100483

### OBJECTS OF THE INVENTION

Currently, in dye-sensitized solar cells, various schemes have been devised in order to improve the conversion efficiency. However a further improvement in conversion efficiency is anticipated. Therefore, an object of the present invention is to provide a dye-sensitized solar cell having a structure that contributes to an improvement in photoelectric conversion efficiency.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

In order to solve the problems mentioned above, in the present invention, in a dye-sensitized solar cell comprising a first electrode having a photoelectric conversion layer, a second electrode disposed so as to oppose the first electrode, and electrolyte filled at least in between the first electrode and second electrode, the first electrode is constructed with a plurality of first electrode layers disposed superposed in a direction that opposes to the second electrode.

According to the present invention mentioned above, the light that has not been absorbed on the single first electrode layer can be absorbed on the first electrode layer of the lower layer, and there is an effect of an improvement in photoelectric conversion efficiency (light absorption efficiency). That is to say, the light that has passed through an (anode) electrode on the first layer can also be effectively photoelectrically converted, and photoelectric conversion efficiency per unit area can be improved. Normally, if the porous titanium dioxide photoelectric conversion layer on which the dye has been adsorbed is made to be a thick coating in order to improve photoelectric conversion efficiency, cracking is likely to occur. However in the present invention, since the three-dimensionally effective porous titanium dioxide coatings (photoelectric conversion layer) are layered, cracking does not occur, and it is possible to improve photoelectric conversion efficiency.

### BRIEF DESCRIPTION OF THE DRAWINGS

FIG. 1 is a sectional explanatory drawing showing a structure of a dye-sensitized solar cell according to a first embodiment of the present invention.

FIG. 2 is an explanatory drawing showing an arrangement of anode electrodes of the dye-sensitized solar cell according to the first embodiment.

FIG. 3 is an internal plan view showing the structure of the dye-sensitized solar cell according to the first embodiment.

FIG. 4 is a graph showing a characteristic of the dye-sensitized solar cell according to the first embodiment.

FIG. 5 is a sectional explanatory drawing showing a structure of a dye-sensitized solar cell according to a second embodiment of the present invention.

FIG. 6 is an explanatory drawing showing an arrangement of anode electrodes of the dye-sensitized solar cell according to the second embodiment.

FIG. 7 is an internal plan view showing the structure of the dye-sensitized solar cell according to the second embodiment.

FIG. 8 is a sectional explanatory drawing showing a structure of a dye-sensitized solar cell according to a third embodiment of the present invention.

FIG. 9 is an explanatory drawing showing a structure of an anode electrode of the dye-sensitized solar cell according to the third embodiment.

FIG. 10 is an internal plan view showing the structure of the dye-sensitized solar cell according to the third embodiment.

FIG. 11 is a sectional explanatory drawing showing a structure of a dye-sensitized solar cell according to a fourth embodiment of the present invention.

FIG. 12 is an internal plan view showing the structure of the dye-sensitized solar cell according to the fourth embodiment.

FIG. 13 is a sectional explanatory drawing showing a structure of a dye-sensitized solar cell according to a fifth embodiment of the present invention.

FIG. 14 is an internal plan view showing the structure of the dye-sensitized solar cell according to the fifth embodiment.

FIG. 15 is an explanatory drawing showing arrangements of anode electrodes and cathode electrodes of the dye-sensitized solar cell according to the fifth embodiment.

FIG. 16 is a sectional explanatory drawing showing a structure of a dye-sensitized solar cell according to a sixth embodiment of the present invention.

FIG. 17 is an internal plan view showing the structure of the dye-sensitized solar cell according to the sixth embodiment.

FIG. 18 is an explanatory drawing showing arrangements of anode electrodes and cathode electrodes of the dye-sensitized solar cell according to the sixth embodiment.

FIG. 19 is a sectional explanatory drawing showing a structure of a dye-sensitized solar cell according to a seventh embodiment of the present invention.

FIG. 20 is an internal plan view showing the structure of the dye-sensitized solar cell according to the seventh embodiment.

FIG. 21 is an explanatory drawing showing arrangements of anode electrodes and cathode electrodes of the dye-sensitized solar cell according to the seventh embodiment.

FIG. 22 is a sectional explanatory drawing showing a structure of a dye-sensitized solar cell according to an eighth embodiment of the present invention.

FIG. 23 is an explanatory drawing showing a structure of an anode electrode of the dye-sensitized solar cell according to the eighth embodiment.

FIG. 24 is an explanatory drawing showing a structure of a cathode electrode of the dye-sensitized solar cell according to the eighth embodiment.

FIG. 25 is a plan view showing another structure embodiment of a meshed electrode of the dye-sensitized solar cell according to the present invention.

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

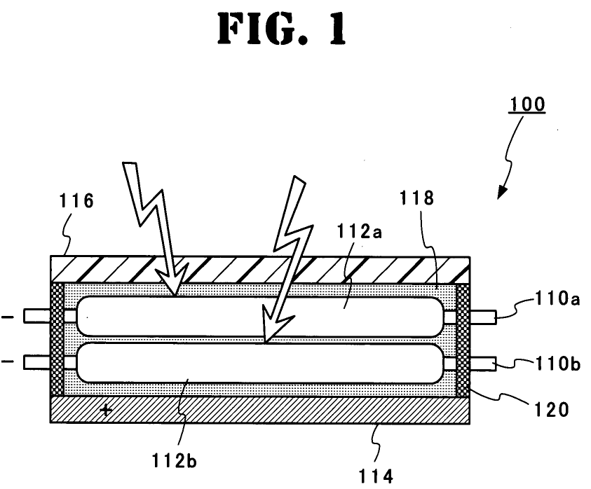

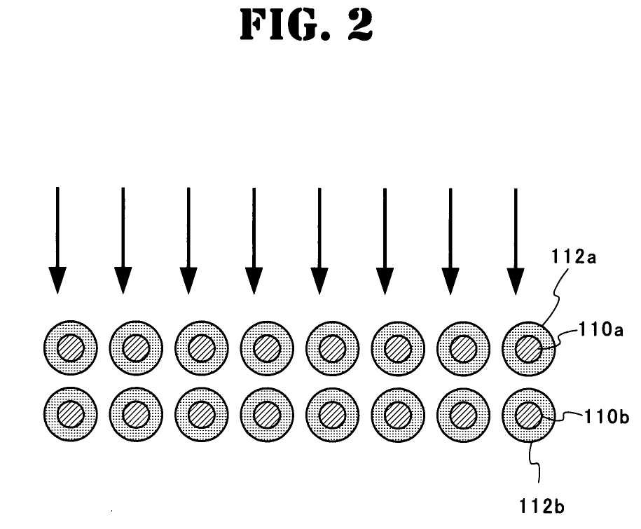

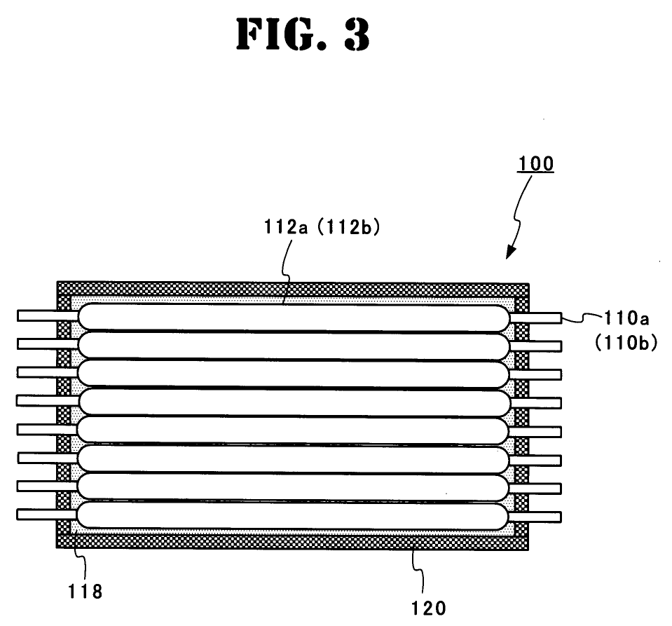

Hereinafter embodiments of the present invention are described in detail. FIG. 1 is a sectional explanatory drawing showing a structure of a dye-sensitized solar cell 100 according to a first embodiment of the present invention. FIG. 2 is an explanatory drawing showing an arrangement of anode electrodes of the dye-sensitized solar cell according to the first embodiment, showing the appearance viewed from the side in FIG. 1. FIG. 3 is an internal plan view showing the structure of the dye-sensitized solar cell 100 according to the first embodiment, showing a status with an upper transparent substrate (116) removed.

The dye-sensitized solar cell 100 according to the first embodiment is provided with: a first anode electrode layer (110a, 112a) including a plurality of first anode fine metallic wires 110a and porous titanium dioxide coatings 112a, serving as photoelectric conversion layers, formed on outer circumferences of the first anode electrode fine wires 110a; a second anode electrode layer (110b, 112b) including a plurality of second anode fine metallic wires 110b and porous titanium dioxide coatings 112b formed on outer circumferences of the second anode electrode fine wires 110b; a cathode electrode plate 114 disposed on the second anode electrode layer side (lower side); an electrolyte (iodine) 118 filled at least in between the first and second anode electrode layers and the cathode electrode plate 114; a transparent substrate (glass or plastic) 116 disposed on an opposite side of the anode electrode layer to the cathode electrode plate 114 (upper side=light input side); and sealing material 120 that seals the electrolyte 118 together with the transparent substrate 116.

As shown in FIG. 1 and FIG. 2, the first anode electrode layer (110a, 112a) and the second anode electrode layer (110b, 112b) are disposed so as to be superposed in two layers in the light input direction or the direction toward the cathode electrode 114. The number of fine metallic wires that construct the first and second anode electrode layers is not limited in particular. Moreover, the number of anode electrode layers to be superposed is not limited to two, and they may be superposed in three or more layers where necessary.

Next, the manufacturing method for the dye-sensitized solar cell 100 is described. First, paste material containing fine TiO₂ particles of approximately 10 to 30 nm is coated on fine metallic wires of approximately 100 μm diameter. As the fine metallic wires 110a and 110b, fine tungsten wires, fine stainless wires coated with FTO, or fine wires for which a top most surface metallic layer having a titanium layer on the surface has been oxidized, may be used. The wire diameter of the fine metallic wires 110a and 110b is approximately 100 μm, and the coating thickness is approximately 30 μm after the titanium dioxide paste has been coated. The titanium dioxide paste is not coated on both end sections of the fine metallic wires 110a and 110b. Alternatively, the titanium dioxide paste may be removed after the sintering process after coating has been carried out on the entire surface.

Next, depending on which type of paste material is used, the metallic wires are subjected to an annealing process for approximately one hour at 100 to 500° C., and the titanium dioxide paste material is sintered to form porous titanium dioxide layers 112a and 112b. As a result, the paste solvent is spattered and the fine titanium dioxide particles neck, forming diffusion passages for electrons. The coating thickness of the porous titanium dioxide layers 112a and 112b is approximately 5 to 15 μm.

Next, the substrate that has been subjected to this sintering process is immersed in an alcohol solution containing Ru metal complex (representative example: N719) for approximately half a day to have Ru metal complex dyes adsorbed on the surface of the TiO₂ of the porous structure. As shown in FIG. 3, a large number of units as structures in which porous titanium dioxide is formed on the fine metallic wires, are arranged in parallel. At this time, the structure bodies (anode electrode layers) are superposed in two layers as described above.

Here, as the dye to be adsorbed on the surfaces of the porous titanium dioxide layers 112a and 112b, the same dye (that absorbs light within the same wavelength range) may be used. Moreover, in order to be able to absorb light of a different frequency, a different dye may be adsorbed. For example, a dye that absorbs light of a short wavelength is adsorbed on the first anode electrode layer (112a), and a dye that absorbs light of a long wavelength is adsorbed on the second anode electrode layer (112b). Dyes such as N3 dye, N719 dye and black dye may be used. For example, N719 dye may be adsorbed on the porous titanium dioxide layer 112a, and black dye may be adsorbed on the layer 112b.

Thus, by combining dyes of different light absorption lengths, a solar cell that absorbs a wavelength range broader than one that uses a single dye can be constructed. In the case where a plurality of types of dye are combined and adsorbed on the same titanium dioxide layer, electric current leakage occurs, causing a reduction in photoelectric conversion efficiency. On the other hand, in the present embodiment, dyes of different types are separated from each other, and therefore such a problem does not occur.

Next, this two layer assembly body (anode electrode layer) is sandwiched between the cathode electrode plate 114 (metallic plate) coated with Pt, and the transparent substrate 116 with a portion formed with a pin hole (not shown in the drawing). Then after forming the sealing material 120 (photo-curing liquid sealing agent (31X-101 manufactured by ThreeBond Co. Ltd.)) around the assembled body, ultraviolet rays of approximately 3000 mJ/cm2 are irradiated thereon to seal it.

Next, the electrolyte 118 containing iodine is injected from the pin hole formed in the transparent substrate 116, and the gap between the two electrodes (anode and cathode) is filled with this electrolyte 118. Subsequently, the pin-hole is sealed, negative electrode wiring is connected to the fine metallic wires 110a and 110b, and positive electrode wiring is connected to the cathode electrode plate 114, to thereby construct the dye-sensitized solar cell.

For the transparent substrate (light transmitting substrate) 116 shown in the present embodiment, a plastic film or the like may be used instead of a glass substrate. However, also in this case, an anti-corrosion property for the electrolyte 118 is still required, and an anti-corrosion material is coated on the surface as necessary.

In the dye-sensitized solar cell 100 having the structure described above, the light that has been transmitted through the transparent substrate 116 is absorbed by the dye adsorbed on the porous titanium dioxide coating 112a that constructs the first anode electrode layer, and electrons are excited. The light that is not absorbed by the first anode electrode layer is absorbed by the dye on the surface of the porous titanium dioxide coating 112b that constructs the second anode electrode layer, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through a conductive coating on the glass to operate an external load, and then reach the positive electrode side. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

According to the present embodiment, there is an effect of a significant reduction in anode side internal resistance. Conventionally, a glass substrate coated with a transparent conductive coating such as FTO and ITO, or a PET film or the like were used. However, in the present embodiment, since fine metallic wires are used, the internal resistance in a practical cell (10 cm □ or greater) can be reduced by one digit even with 100 μm diameter shown in the embodiment, compared to the case of using a transparent conductive coating. As a result, energy loss caused by internal resistance can be significantly reduced, and an improvement in conversion efficiency can be expected. Furthermore, formation of metallic electrodes such as bus bar electrodes and finger electrodes that were essential in a large area cell in the conventional technique is not necessarily required. As a result, a cost reduction can be achieved since extra steps can be omitted, and a solar battery cell of a numerical aperture of 100% can be constructed, thus contributing to the realization of a high performance (high efficiency) dye-sensitized solar cell.

Moreover, the light transmitting plate (glass substrate, plastic film) does not need to have a conductive function, so there is an effect of cost reduction. In the conventional dye-sensitized solar cell, the transparent conductive coating formed on the glass substrate or the plastic film used for light transmission was expensive. In contrast, in the present embodiment, an inexpensive material can be used for the glass substrate or film, and recycled waste plastic film or glass can be used. This is because, the role of the glass substrate or plastic film shown in the present embodiment is only to transmit light and seal off the electrolyte, and glass or film coated with an expensive conductive coating is not required. Furthermore, in the conventional film type light transmitting plate, when titanium dioxide paste is sintering-processed on the film, the sintering temperature is rate-controlled (150° C. or less) and necking is limited. Hence the internal resistance of the porous titanium dioxide itself is not sufficiently reduced. In the present embodiment, since titanium dioxide is formed on the transparent film, heat resistance of the plastic is not a problem. Therefore, the present embodiment significantly contributes to achieving a high performance dye-sensitized solar cell of both of a glass type and a film type, and to a cost reduction.

Moreover, since the dye adsorption coating such as the titanium dioxide coating is formed on the surface of the fine metallic wires, there are effects including an increase in the area of the titanium dioxide coating surface, and an improvement in conversion efficiency.

Furthermore, in the present embodiment, the light that has been transmitted through the upper layer anode electrode can be efficiently photoelectrically converted in the lower layer anode electrode, and the conversion efficiency per unit area can be improved. Normally, cracking is likely to occur if the porous titanium dioxide photoelectric conversion layer is made to be a thick coating in order to improve photoelectric conversion efficiency. However in the present embodiment, since the three-dimensionally effective porous titanium dioxide coatings are layered, cracking does not occur, and it is possible to improve photoelectric conversion efficiency.

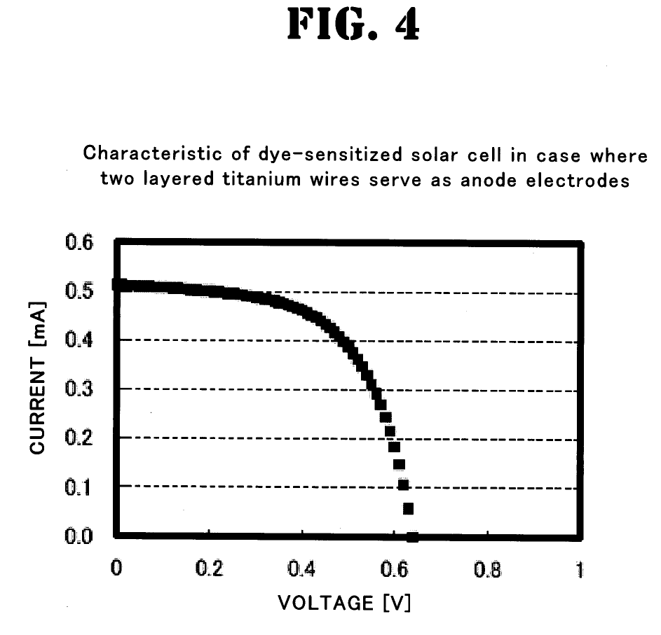

FIG. 4 shows a characteristic of the dye-sensitized solar cell in the case where two layered titanium wires serve as anode electrodes. As shown in FIG. 4, the maximum output of the dye-sensitized solar cell according to the present embodiment is approximately 0.2 mW when the output operation voltage is 0.47 V, and the output operation current is 0.42 mA.

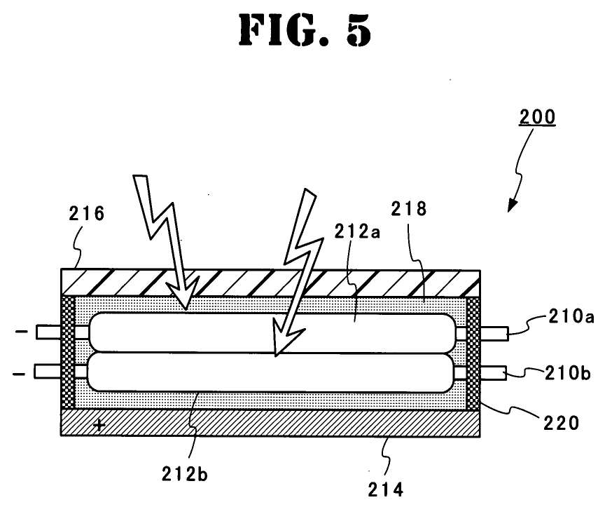

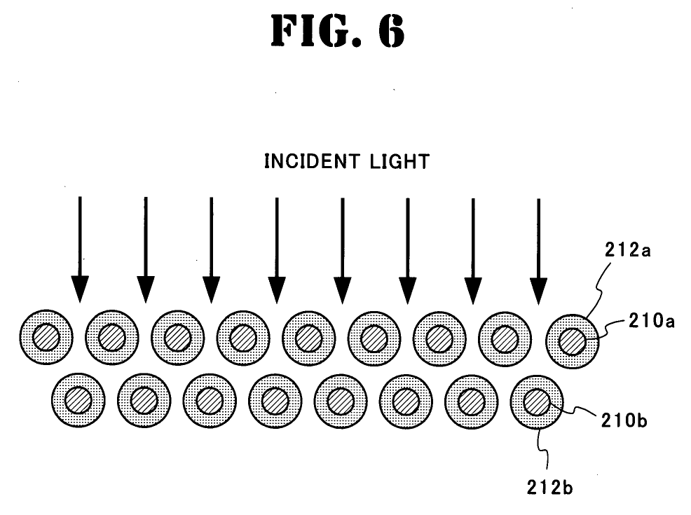

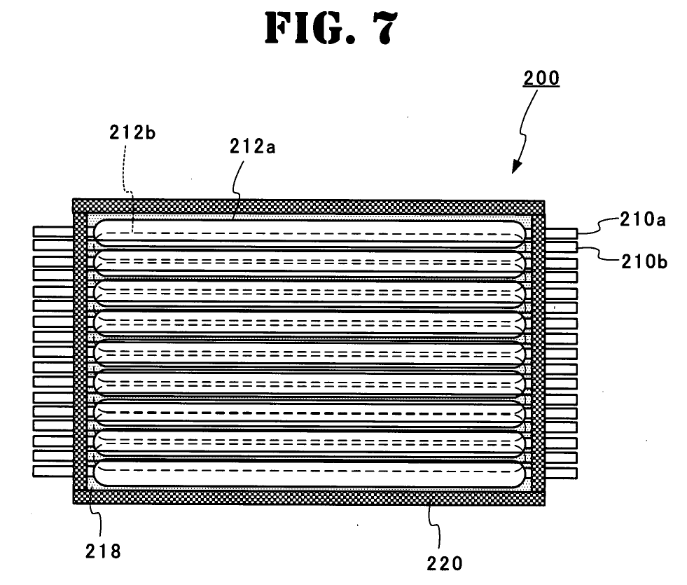

FIG. 5 is a sectional explanatory drawing showing a structure of a dye-sensitized solar cell 200 according to a second embodiment of the present invention. FIG. 6 is an explanatory drawing showing an arrangement of anode electrodes of the dye-sensitized solar cell 200 according to the second embodiment. FIG. 7 is an internal plan view showing the structure of the dye-sensitized solar cell 200 according to the second embodiment. The present embodiment is a modified embodiment of the first embodiment, and differs from the first embodiment in that the upper and lower anode electrode layers disposed in two layers are not horizontally aligned.

The dye-sensitized solar cell 200 according to the second embodiment is provided with: a first anode electrode layer including a plurality of first anode fine metallic wires 210a and porous titanium dioxide coatings 212a formed on the outer circumferences of the first anode electrode fine wires 210a; a second anode electrode layer including a plurality of second anode fine metallic wires 210b and porous titanium dioxide coatings 212b formed on outer circumferences of the second anode electrode fine wires 210b; a cathode electrode plate 214 disposed on the second anode electrode layer side (lower side); electrolyte (iodine) 218 filled at least in between the first and second anode electrode layers and the cathode electrode plate 214; a transparent substrate (glass or plastic) 216 disposed on a side opposite of the cathode electrode plate 214; and sealing material 220 that seals the electrolyte together with the cathode electrode plate 214 and the transparent substrate 216.

As shown in FIG. 5 and FIG. 6, the first anode electrode layer (210a, 212a) and the second anode electrode layer (210b, 212b) are disposed so as to be superposed in two layers in the light input direction or the direction toward the cathode electrode 214. The number of fine metallic wires that construct the first and second anode electrode layers is not limited in particular. Moreover, the number of anode electrode layers to be superposed is not limited to two, and they may be superposed in three or more layers where necessary. Here, the present embodiment differs from the above first embodiment in that the upper and lower anode electrode layers disposed in two layers are not horizontally aligned. As described above, due to the non-aligned disposition, the light that has passed through the gaps in the first anode electrode layer (upper layer) can be absorbed by the second anode electrode layer.

Similarly to the case of the first embodiment, as the dye to be adsorbed on the surfaces of the porous titanium dioxide layers 212a and 212b, the same dye (that absorbs light within the same wavelength range) may be used. Moreover, in order to be able to absorb light of a different frequency, a different dye may be adsorbed. For example, a dye that absorbs light of a short wavelength is adsorbed on the first anode electrode layer (212a), and a dye that absorbs light of a long wavelength is adsorbed on the second anode electrode layer (212b).

Dyes such as N3 dye, N719 dye and black dye may be used. For example, N719 dye may be adsorbed on the porous titanium dioxide layer 112a, and black dye may be adsorbed on the layer 112b.

Thus, by combining dyes of different light absorption lengths, a solar cell that absorbs a wavelength range broader than one that uses a single dye can be constructed. In the case where a plurality of types of dyes are combined and adsorbed on the same titanium dioxide layer, electric current leakage occurs, causing a reduction in photoelectric conversion efficiency. On the other hand, in the present embodiment, dyes of different types are separated from each other, and therefore such a problem does not occur.

A method the same as that of the first embodiment may be employed as the manufacturing method for the dye-sensitized solar cell, and repeated description is omitted. Moreover, in addition to the effects of the first embodiment, a further improvement in photoelectric conversion can be expected.

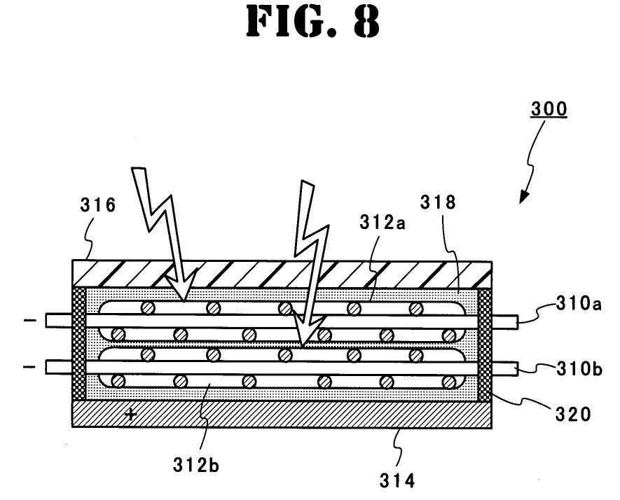

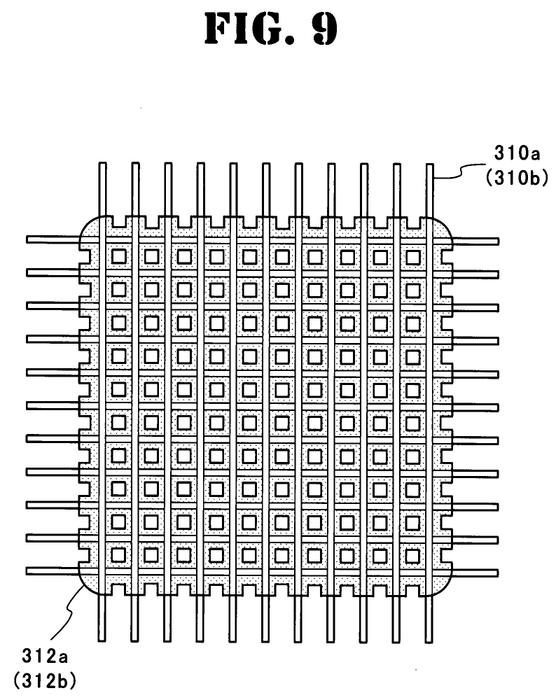

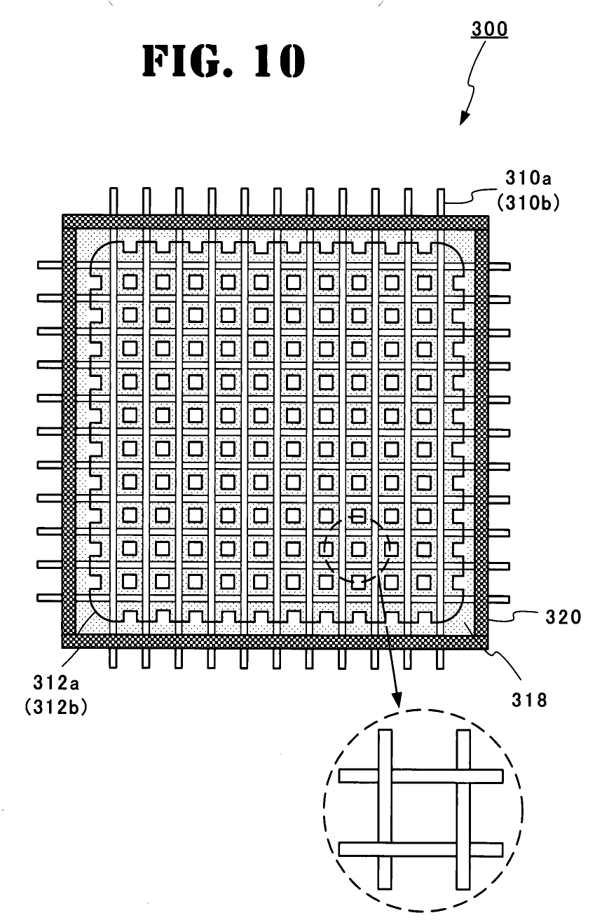

FIG. 8 is a third explanatory drawing showing a structure of a dye-sensitized solar cell 300 according to a third embodiment of the present invention. FIG. 9 is an explanatory drawing showing a structure of an anode electrode of the dye-sensitized solar cell 300 according to the third embodiment. FIG. 10 is an internal plan view showing the structure of the dye-sensitized solar cell 300 according to the third embodiment.

Compared to the cell 100 according to the first embodiment, the dye-sensitized solar cell 300 according to the present embodiment differs in that the structure of the anode electrode layer has the photoelectric conversion layer. That is to say, this differs in that, in the first embodiment the porous titanium dioxide coating is formed on the outer circumferential surface of the rod shaped fine metallic wire, whereas in the present embodiment the fine metallic wire is formed in a mesh form.

The dye-sensitized solar cell 300 according to the third embodiment is provided with: a first anode electrode layer (310a, 312a) including a first anode metallic mesh 310a and a porous titanium dioxide coating 312a formed on the first anode metallic mesh 310a; a second anode electrode layer (310b, 312b) including a second anode metallic mesh 310b and a porous titanium dioxide coating 312b formed on the second anode metallic mesh 310b; a cathode electrode plate 314 disposed on the second anode electrode layer side (lower side); electrolyte (iodine) 318 filled at least in between the first and second anode electrode layers and the cathode electrode plate 314; a transparent substrate (glass or plastic) 316 disposed on an opposite side to the cathode electrode plate 314; and sealing material 320 that seals the electrolyte 118 together with the cathode electrode plate 314 and the transparent substrate 316.

As shown in FIG. 8, the first anode electrode layer (310a, 312a) and the second anode electrode layer (310b, 312b) are disposed so as to be superposed in two layers in the light input direction or the direction toward the cathode electrode 314. The interval in the metallic mesh that constructs the first and second anode electrode layers is not limited in particular. Moreover, the number of anode electrode layers to be superposed is not limited to two, and they may be superposed in three or more layers where necessary. The actual way of lacing (weaving) the metallic meshes 310a and 310b is such that they are alternately woven in the vertical and horizontal directions as shown in the enlargement in FIG. 10.

Next, a manufacturing method for the dye-sensitized solar cell 100 is described. First, paste material containing fine TiO₂ particles of approximately 10 to 30 nm is coated on the metallic meshes 310a and 310b of approximately 50 μm diameter with an inter-wiring gap of approximately 50 μm. As the metallic meshes 310a and 310b, fine tungsten wires, fine stainless wires coated with FTO, or fine wires for which a top most surface metallic layer having a titanium layer on the surface has been oxidized, may be used. The titanium dioxide paste is not coated on the outer circumferential surfaces of the metallic meshes 310a and 310b. Alternatively, the titanium dioxide coating on the outer circumferential surfaces may be removed after the sintering process after coating has been carried out on the entire surface.

Next, depending on which type of paste material is used, the metallic meshes are subjected to an annealing process for approximately one hour at 100 to 500° C., and the titanium dioxide paste material is sintered to form porous titanium dioxide layers 312a and 312b. As a result, polyethylene glycol, which is the paste solvent, is spattered and fine titanium dioxide particles neck, forming diffusion passages for electrons. The coating thickness of the porous titanium dioxide layers 312a and 312b is approximately 5 to 15 μm. This coating and sintering processes may be carried out several times. In the case where the coating thicknesses of the porous titanium dioxide layers 312a and 312b are greater than the gaps in the mesh, these gaps are completely filled with titanium dioxide, while in the case where the coating thicknesses of the porous titanium dioxide layers 312a and 312b are less than the gaps, minute holes are formed in the gap section. In the present embodiment, the gaps may be completely filled or may have holes therein.

Next, the substrate that has been subjected to this sintering process is immersed in an alcohol solution containing Ru metal complex (representative example: N719) for approximately half a day to have Ru metal complex dyes adsorbed on the surface of the TiO₂ of the porous structure.

As the dye to be adsorbed on the surfaces of the porous titanium dioxide layers 312a and 312b, the same dye (that absorbs light within the same wavelength range) may be used. Moreover, in order to be able to absorb light of a different frequency, a different dye may be adsorbed. For example, a dye that absorbs light of a short wavelength is adsorbed on the first anode electrode layer (312a), and a dye that absorbs light of a long wavelength is adsorbed on the second anode electrode layer (312b). Dyes such as N3 dye, N719 dye and black dye may be used. For example, N719 dye may be adsorbed on the porous titanium dioxide layer 312a, and black dye may be adsorbed on the layer 312b.

Thus, by combining dyes of different light absorption lengths, a solar cell that absorbs a wavelength range broader than one that uses a single dye can be constructed. In the case where a plurality of types of dye are combined and adsorbed on the same titanium dioxide layer, electric current leakage occurs, causing a reduction in photoelectric conversion efficiency. On the other hand, in the present embodiment, dyes of different types are separated from each other, and therefore such a problem does not occur.

Next, the first and second node electrode layers are sandwiched between the cathode metallic plate 314 coated with Pt, and the transparent substrate 316 formed with a pin hole. Then after forming the photo-curing liquid type sealing agent 320 (31X-101 manufactured by ThreeBond Co. Ltd.) around these layers, ultraviolet rays of approximately 3000 mJ/cm2 are irradiated thereon to seal it. This process may be replaced with a process where Hafumiran film manufactured by Mitsui DuPont Co. Ltd. is disposed as the sealing material on the metallic plate, the metallic meshes 310a and 310b are placed thereon, the same film is disposed further thereon, and it is fused at approximately 120° C.

Next, after injecting the electrolyte 318 containing iodine through the pin hole formed in the transparent substrate 316, and filling the gap between the two electrodes with the electrolyte 318, the pin hole is sealed. Subsequently, negative electrode wiring is connected to the metallic meshes 310a and 310b, and positive electrode wiring is connected to the cathode electrode plate 314, to thereby construct the dye-sensitized solar cell.

For the transparent substrate 316, a plastic film or the like may be used other than a glass substrate. However, also in this case, an anti-corrosion property for the electrolyte is still required, and an anti-corrosion material is coated on the surface as necessary.

In the dye-sensitized solar cell 300 having the structure described above, the light that has been transmitted through the transparent substrate 316 is absorbed by the dye adsorbed on the porous titanium dioxide coating 312a that constructs the first anode electrode layer, and electrons are excited. The light that is not absorbed by the first anode electrode layer is absorbed by the dye on the surface of the porous titanium dioxide coating 312b that constructs the second anode electrode layer, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through a conductive coating on the glass to operate an external load, and then reach the positive electrode side. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

According to the present embodiment, since the metallic meshes 310a and 310b are used for the anode electrode layer, then in addition to the effects of the first embodiment mentioned above, there are effects in which the top surface area of the dye adsorption coating such as the titanium dioxide coating further increases, and photoelectric conversion efficiency is improved.

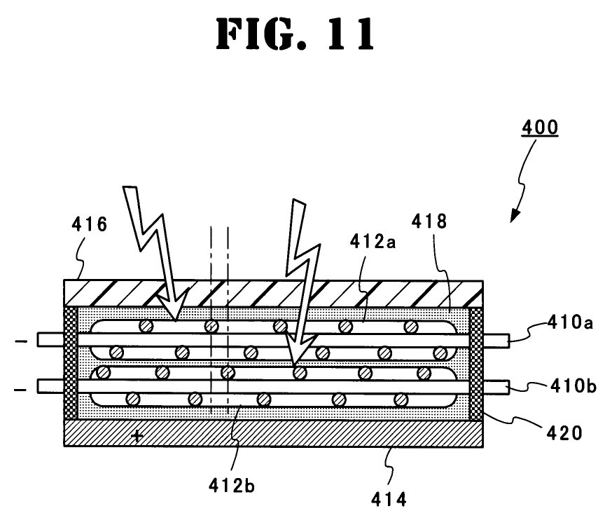

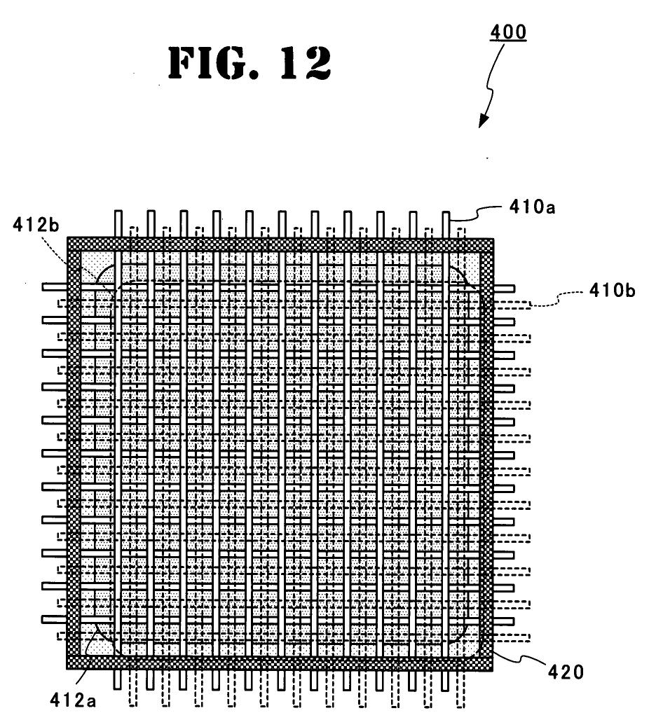

FIG. 11 is a sectional explanatory drawing showing a structure of a dye-sensitized solar cell 400 according to a fourth embodiment of the present invention. FIG. 12 is an internal plan view showing the structure of the dye-sensitized solar cell 400 according to the fourth embodiment. The present embodiment is a modified embodiment of the third embodiment, and differs from the first embodiment in that the upper and lower anode electrode layers disposed in two layers are not horizontally aligned.

The basic structure, the manufacturing method, and the selection of dye to be used for this embodiment are the same as for the third embodiment mentioned above, and repeated description is omitted. Moreover, the actual way of lacing (weaving) the metallic meshes 410a and 410b is such that they are alternately woven in the vertical and horizontal directions as shown in the enlargement in FIG. 10, similarly to the case of the third embodiment.

In the present embodiment, the metallic mesh 410a that constructs the first anode electrode layer, and the metallic mesh 410b that constructs the second anode electrode layer, are disposed so as to be superposed in two layers in the light input direction or the direction toward the cathode electrode 414. The upper and lower anode electrode layers disposed in two layers are not aligned. As described above, due to the non-aligned disposition, the light that has passed through the gaps in the first anode electrode layer (upper layer) can be absorbed by the second anode electrode layer. The direction in which the two metallic meshes are out of alignment can be either the longitudinal/transverse direction or the diagonal direction.

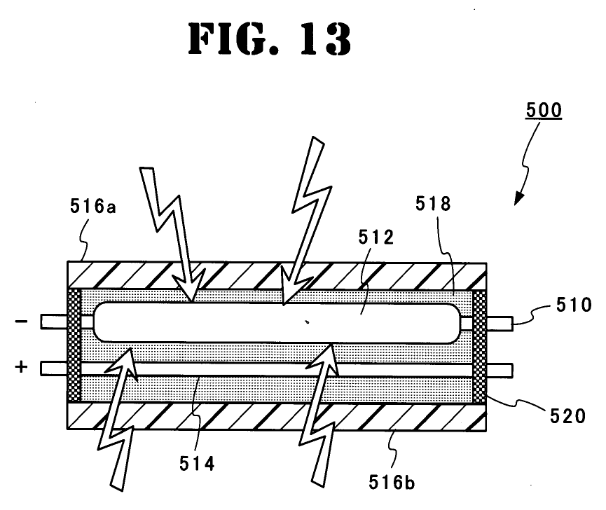

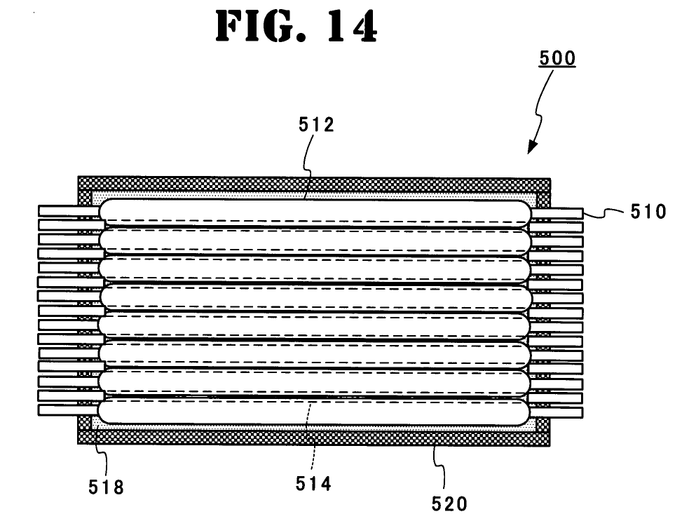

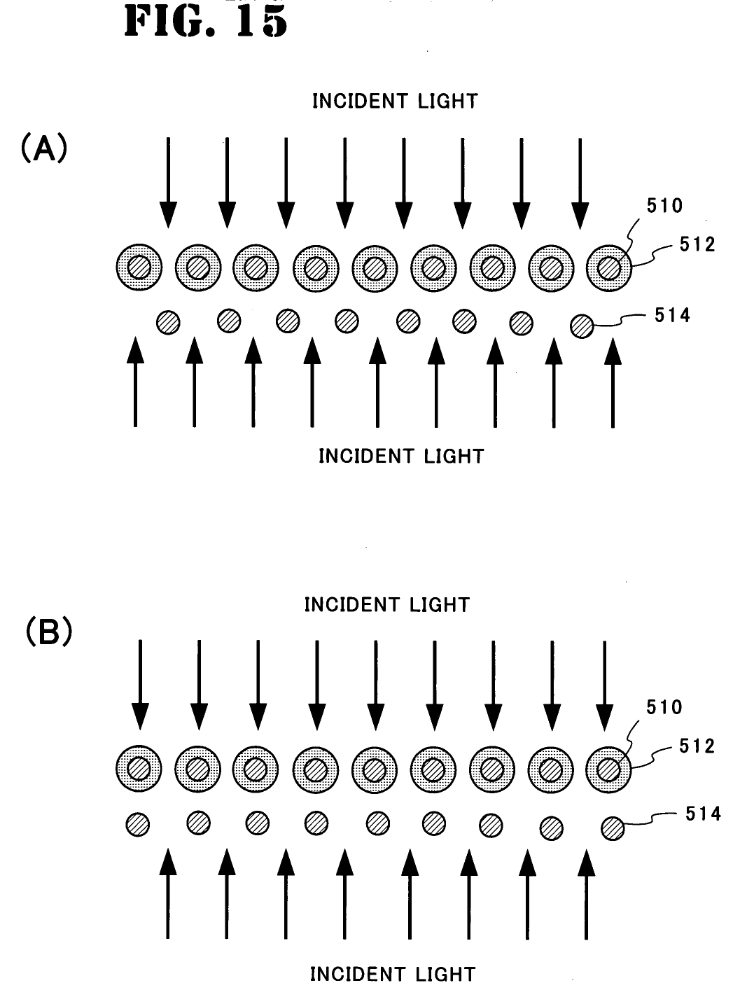

FIG. 13 is a sectional explanatory drawing showing a structure of a dye-sensitized solar cell 500 according to a fifth embodiment of the present invention. FIG. 14 is an internal plan view showing the structure of the dye-sensitized solar cell 500 according to the fifth embodiment. FIG. 15 is an explanatory drawing showing arrangements of anode electrodes and cathode electrodes of the dye-sensitized solar cell 500 according to the fifth embodiment.

The dye-sensitized solar cell 500 according to the fifth embodiment is provided with: an anode electrode layer (510, 512) including a plurality of anode fine metallic wires 510 and porous titanium dioxide coatings 512 formed on the anode fine metallic wires 510; a plurality of fine metallic wires 514 for the cathode electrode disposed so as to oppose the anode electrode layer; an electrolyte (iodine) 518 filled at least in between the anode electrode layer and the cathode electrode; transparent substrates (glass or plastic) 516a and 516b disposed on the anode electrode side (upper side) and the cathode electrode side (lower side); and sealing material 520 that seals the electrolyte 518 together with the transparent substrates 516a and 516b.

The present embodiment has a structure such that the fine metallic wires 514 formed on the surface with a catalyst material that produces a reduction reaction with a redox mediator such as Pt, are used as the cathode electrode (514), and they are arranged side by side. The anode side electrode fine wires 510 and the cathode side fine metallic wires 514 are arranged in a plane shape so as to be parallel with each other. As shown in FIG. 14 and FIG. 15, the anode side electrodes (510 and 512) are arranged in a plane with no space therebetween, whereas the cathode fine wires 514 may be disposed with spaces therebetween. As the fine metallic wires 514, platinum coated copper wires may be used.

As shown in FIG. 15 (A), the fine metallic wires 510 for the anode electrode and the fine metallic wires 514 for the cathode electrode can be alternately disposed in off plane alignment. Alternatively, as shown in FIG. 15 (B), the fine metallic wires 510 for the anode electrode and the fine metallic wires 514 for the cathode electrode may be arranged so as to overlap vertically.

As the fine metallic wires 510 for the anode electrode, fine tungsten wires of approximately 50 μm diameter, fine stainless wires coated with FTO, or fine wires for which a top most surface metallic layer having a titanium layer on the surface has of been oxidized, may be used. The coating thickness of the porous titanium dioxide layer 512 can be approximately 10 to 15 μm. A method the same as that of the first embodiment may be employed as an overall manufacturing method for the dye-sensitized solar cell, and repeated description is omitted.

In the dye-sensitized solar cell 500 having the structure described above, light that has been transmitted through the transparent substrates 516a and 516b is absorbed by the dye adsorbed on the porous titanium dioxide coating 512 that constructs the anode electrode layer, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through the fine metallic wires 510 for the anode electrode, to operate an external load, and then reach the fine metallic wires 514 for the cathode electrode (counter electrode). Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

In the present invention, since the transparent substrates 516a and 516b are disposed on both of the upper and lower sides, there is an advantage in that light can be taken from a broad range, and photoelectric conversion efficiency can be improved. Moreover, since overall transparency can be easily ensured, it can be applied to a window section of a building. Furthermore, the transparent substrates 516a and 516b on both sides can be constructed from flexible plastic films, so that a light weight, thin film type solar cell can be constructed easily.

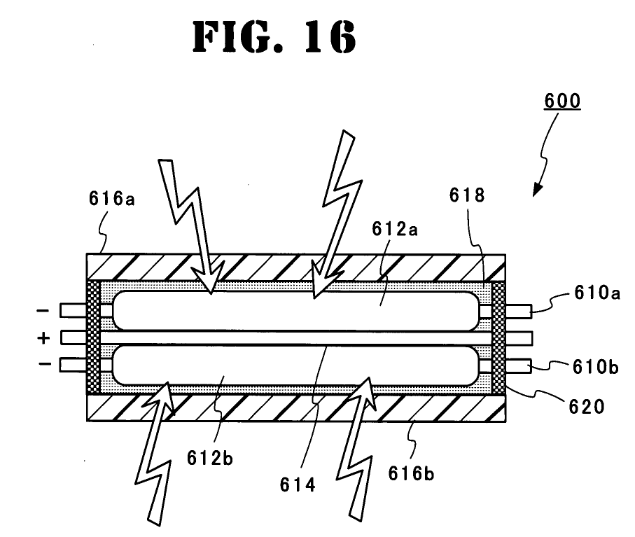

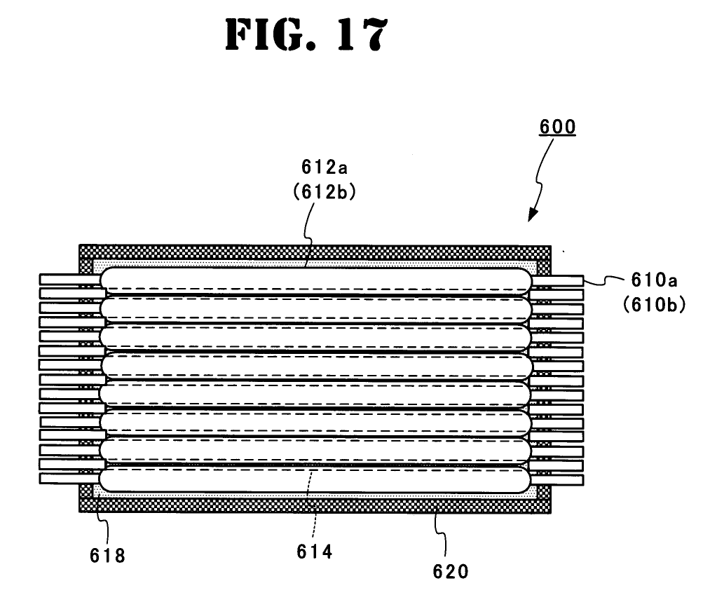

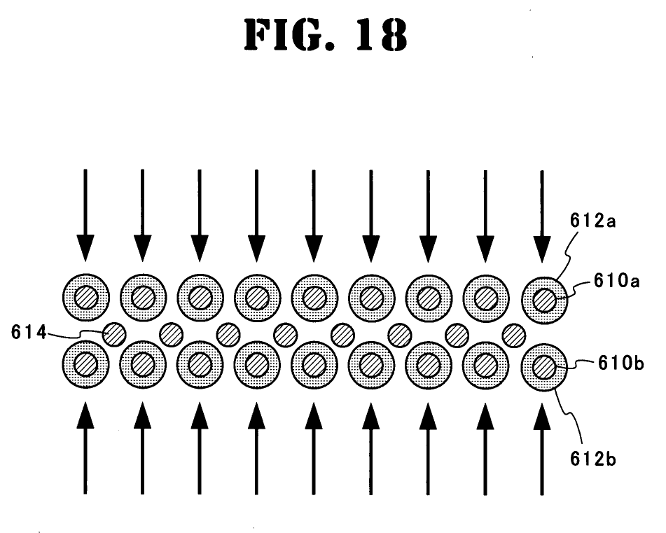

FIG. 16 is a sectional explanatory drawing showing a structure of a dye-sensitized solar cell 600 according to a sixth embodiment of the present invention. FIG. 17 is an internal plan view showing the structure of the dye-sensitized solar cell 600 according to the sixth embodiment. FIG. 18 is an explanatory drawing showing arrangements of anode electrodes and cathode electrodes of the dye-sensitized solar cell 600 according to the sixth embodiment. The present embodiment is a modified embodiment of the fifth embodiment, and differs from the fifth embodiment in that a cathode electrode layer (614) is disposed between two-layered anode electrode layers (610a and 610b).

The dye-sensitized solar cell 600 according to the sixth embodiment is provided with: a first anode electrode layer (610a, 612a) including a plurality of first anode fine metallic wires 610a and porous titanium dioxide coatings 612a formed on outer circumferences of the first anode electrode fine wires 610a; a second anode electrode layer (610b, 612b) including a plurality of second anode fine metallic wires 610b and porous titanium dioxide coatings 612b formed on outer circumferences of the second anode electrode fine wires 610b; a plurality of fine metallic wires 614 for the cathode electrode disposed between the first anode electrode layer (610a) and the second anode electrode layer (610b); an electrolyte (iodine) 618 filled at least in between the anode electrode layers and the cathode electrode; transparent substrates (glass or plastic) 616a and 616b disposed on an anode electrode side (upper side) and on a cathode electrode side (lower side); and sealing material 620 that seals the electrolyte 618 together with the transparent substrates 616a and 616b.

The present embodiment has a structure such that the fine metallic wires 614 formed on the surface with a catalyst material that produces a reduction reaction with a redox mediator such as Pt, are used as the cathode electrode (614), and they are arranged in parallel. The anode side electrode fine wires 610a and 610b and the cathode side fine metallic wires 614 are arranged in a plane shape so as to be parallel with each other. As shown in FIG. 18, the cathode fine metallic wires 614 can be disposed so as to be sandwiched between two adjacent anode side fine electrode wires 610a (610b). As the fine metallic wires 614, platinum coated copper wires may be used.

As the fine metallic wires 610a and 610b for the anode electrode, fine tungsten wires of approximately 100 μm diameter, fine stainless wires coated with FTO, or fine wires for which a top most surface metallic layer having a titanium layer on the surface has been oxidized, may be used. The diameter of the fine metallic wires 610a and 610b is approximately 100 μm. The coating thickness of the porous titanium dioxide layers 612a and 612b can be approximately 5 to 15 μm. A method the same as that of the first embodiment may be employed as an overall manufacturing method for the dye-sensitized solar cell, and repeated description is omitted.

In the dye-sensitized solar cell 600 having the structure described above, light that has been transmitted through the transparent substrates 616a and 616b is absorbed by the dye adsorbed on the porous titanium dioxide coatings 612a and 612b that construct the anode electrode layer, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through the fine metallic wires 610a and 610b for the anode electrode, to operate an external load, and then reach the fine metallic wires 614 on the cathode electrode side. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

In the present invention, since the transparent substrates 616a and 616b are disposed on both of the upper and lower sides, there is an advantage in that light can be taken from a broad range, and photoelectric conversion efficiency can be improved. Moreover, since overall transparency can be easily ensured, it can be applied to a window section of a building. Furthermore, the transparent substrates 616a and 616b on both sides can be constructed from flexible plastic films, so that a light weight, thin film type solar cell can be constructed easily. In addition, compared to the fifth embodiment mentioned above, by adopting the two-layered anode electrode layers, there is the effect that conversion efficiency can be further improved.

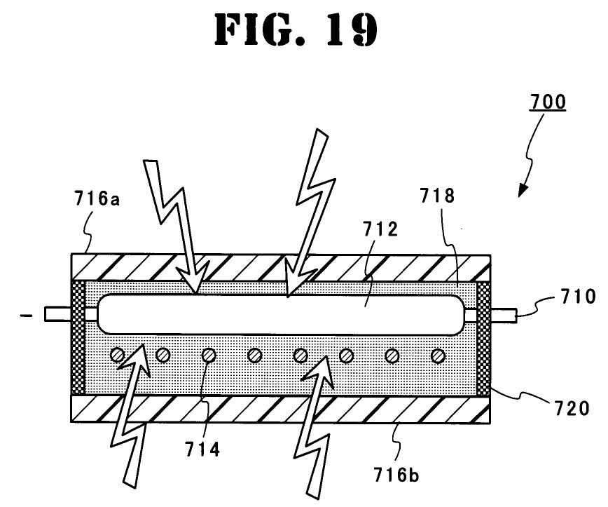

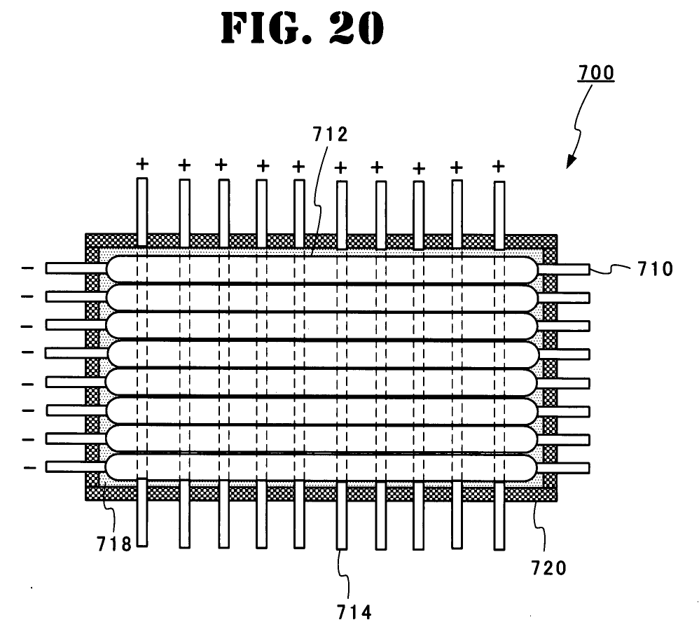

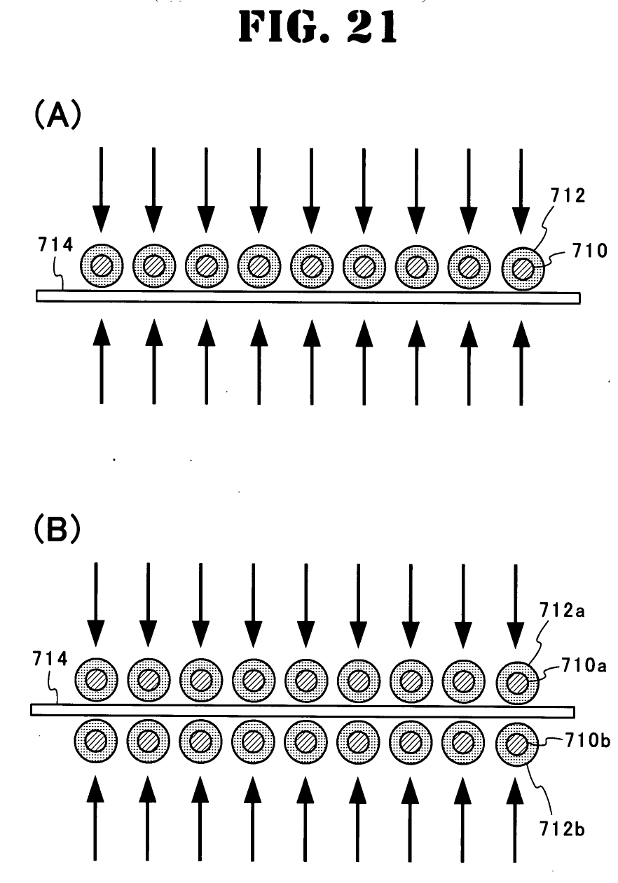

FIG. 19 is a sectional explanatory drawing showing a structure of a dye-sensitized solar cell 700 according to a seventh embodiment of the present invention. FIG. 20 is an internal plan view showing the structure of the dye-sensitized solar cell 700 according to the seventh embodiment. FIG. 21 is an explanatory drawing showing arrangements of anode electrodes and cathode electrodes of the dye-sensitized solar cell 700 according to the seventh embodiment. The present embodiment is a modified embodiment of the fifth embodiment described above, and differs from the fifth embodiment in the disposition of an anode electrode layer (710) and a cathode electrode layer (714). That is to say, in the present embodiment, anode electrode side fine metallic wires 710 and cathode side fine metallic wires 714 are disposed so as to be planewise orthogonal.

The dye-sensitized solar cell 700 according to the seventh embodiment is provided with: an anode electrode layer (710, 712) including a plurality of first anode fine metallic wires 710 and porous titanium dioxide coatings 712 formed on outer circumferences of the anode electrode fine wires 710; a plurality of fine metallic wires 714 for the cathode electrode disposed so as to oppose the anode electrode layer; an electrolyte (iodine) 718 filled at least in between the anode electrode layer and the cathode electrode; transparent substrates (glass or plastic) 716a and 716b disposed on an anode electrode side (upper side) and on a cathode electrode side (lower side); and sealing material 720 that seals the electrolyte 718 together with the transparent substrates 716a and 716b.

The present embodiment has a structure such that the fine metallic wires 714 formed on the surface with a catalyst material that produces a reduction reaction with a redox mediator such as Pt, are used as the cathode electrode (714), and they are arranged side by side. Moreover, as shown in FIG. 20, the anode side electrode fine wires 710 and the cathode side fine metallic wires 714 are laid out in planes so as to be orthogonal to each other. As the fine metallic wires 714, platinum coated copper wires may be used.

As shown in FIG. 21 (A), the fine metallic wires 710 for the anode electrode and the fine metallic wires 714 for the cathode electrode can be disposed so as to be orthogonal to each other. Alternatively, as shown in FIG. 21 (B), the structure may be such that the orthogonal fine metallic wires 714 for the cathode electrode are sandwiched between the two layered fine metallic wires 710a and 710b for the anode electrode.

As the fine metallic wires 710 for the anode electrode, fine tungsten wires of approximately 50 μm diameter, fine stainless wires coated with FTO, or fine wires for which a metallic surface has been coated with titanium and the surface oxidized, may be used. The coating thickness of the porous titanium dioxide layer 713 can be approximately 5 to 15 μm. A method the same as that of the first embodiment may be employed as an overall manufacturing method for the dye-sensitized solar cell, and repeated description is omitted.

In the dye-sensitized solar cell 700 having the structure described above, light that has been transmitted through the transparent substrates 716a and 716b is absorbed by the dye adsorbed on the porous titanium dioxide layer 716 that constructs the anode electrode layer, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through the fine metallic wires 710 for the anode electrode, to operate an external load, and then reach the fine metallic wires 714 for the cathode electrode. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

In the present invention, since the transparent substrates 716a and 716b are disposed on both of the upper and lower sides, there is an advantage in that light can be taken from a broad range, and conversion efficiency can be improved. Moreover, since the overall transparency can be easily ensured, it can be applied to a window section of a building. Furthermore, the transparent substrates 716a and 716b on both sides can be constructed from flexible plastic films, so that a light weight, thin film type solar cell can be constructed easily. Furthermore, the anode electrode and the cathode electrode can be taken out to the outside of the cell in different directions (from different sides of the rectangle), so that there is an advantage in increased freedom of design.

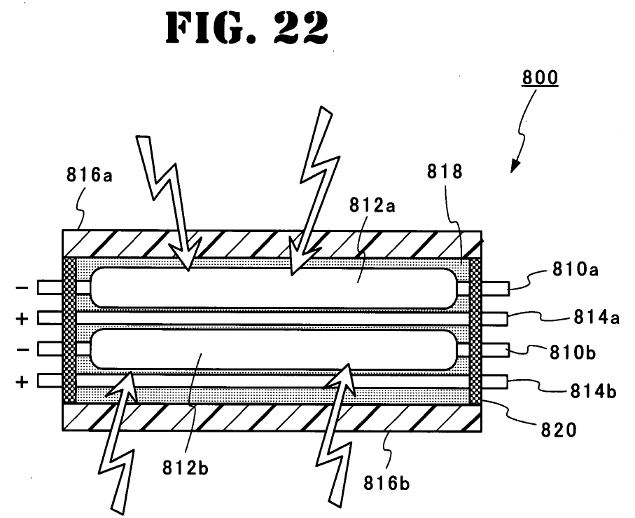

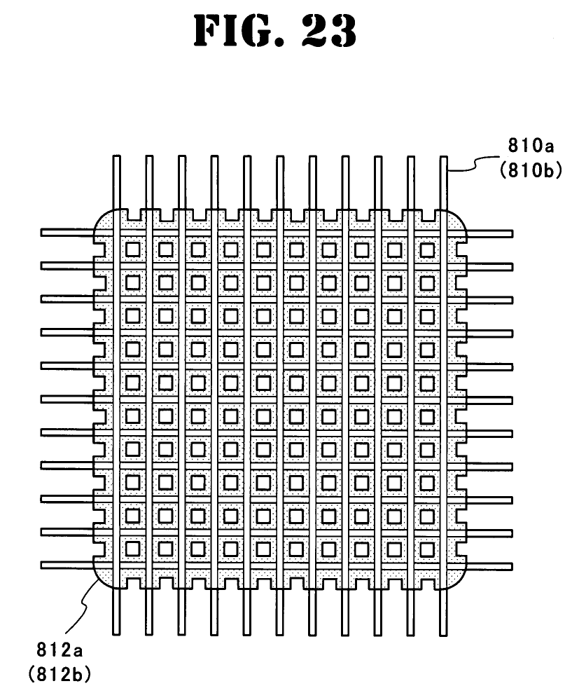

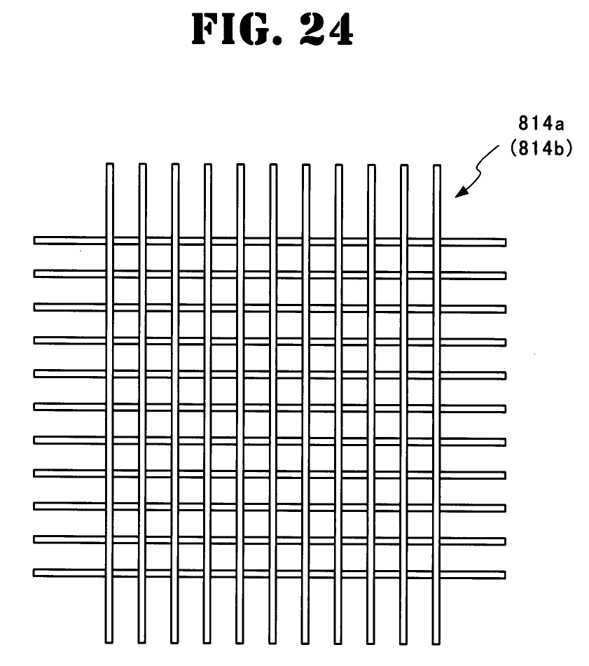

FIG. 22 is a sectional explanatory drawing showing a structure of a dye-sensitized solar cell 800 according to an eighth embodiment of the present invention. FIG. 23 is an explanatory drawing showing a structure of an anode electrode of the dye-sensitized solar cell 800 according to the eighth embodiment. FIG. 24 is an explanatory drawing showing a structure of a cathode electrode of the dye-sensitized solar cell 800 according to the eighth embodiment. The present embodiment is configured by combining technical ideas of the third embodiment and the sixth embodiment described above. That is to say, it is a configuration in which metallic mesh is employed as the cathode electrode in addition to the anode electrode, and the cathode electrode is disposed in the electrolyte, and light inputted from both of the top and bottom surfaces is absorbed to perform photoelectric conversion.

The dye-sensitized solar cell 800 according to the eighth embodiment is provided with: a first anode electrode layer (810a, 810b) including a first anode metallic mesh 810a and a porous titanium dioxide coatings 812a formed on the surface of the first anode metallic mesh 810a; a second anode electrode layer (810b, 812b) including a second anode metallic mesh 810b and a porous titanium dioxide coating 812b formed on the surface of the second anode metallic mesh 810b; a first cathode metallic mesh 814a disposed between the first anode electrode layer (810a, 812a) and the second anode electrode layer (810b, 812b); a second cathode metallic mesh 814b disposed below the second anode electrode layer (810b, 812b); an electrolyte (iodine) 818 filled at least in between the anode electrode layer and the cathode electrode layer; transparent substrates (glass or plastic) 816a and 816b disposed on the first anode electrode side (upper side) and on the second cathode electrode side (lower side); and sealing material 820 that seals the electrolyte 818 together with the transparent substrates 816a and 816b.

In the present embodiment, metallic meshes formed on the surface with a catalyst material that produces a reduction reaction with a redox mediator such as Pt, are used as the cathode electrode (814a, 814b). Moreover, the anode side electrode meshes 810a, 810b, and the cathode side metallic meshes 814a, 814b are alternately overlapped in parallel. As the fine metallic wires 814a and 814b, platinum coated copper wires may be used.

Next, a manufacturing method for the dye-sensitized solar cell 800 is described. First, paste material containing fine TiO₂ particles of approximately 10 to 30 nm is coated on the metallic meshes 810a and 810b of approximately 50 μm diameter with an inter-wiring gap of approximately 50 μm. As the metallic meshes 810a and 810b, fine tungsten wires, fine stainless wires coated with FTO, or fine wires for which a top most surface metallic layer having a titanium layer on the surface has been oxidized, may be used. The titanium dioxide paste is not coated on the outer circumferential surfaces of the metallic meshes 810a and 810b. Alternatively, titanium dioxide coating on this outer circumferential surface may be removed after the sintering process after coating has been carried out on the entire surface.

Next, depending on which type of paste material is used, the metallic meshes are subjected to an annealing process for approximately one hour at 100 to 500° C., and the titanium dioxide paste material is sintered to form porous titanium dioxide layers 812a and 812b. As a result, polyethylene glycol, which is the paste solvent, is spattered and fine titanium dioxide particles neck, forming diffusion passages for electrons. The coating thickness of the porous titanium dioxide layers 812a and 812b is approximately 5 to 15 μm. This coating and sintering processes may be carried out several times. In the present embodiment, the case where minute holes are formed in the mesh gap section is shown.

Next, the substrate that has been subjected to this sintering process is immersed in an alcohol solution containing Ru metal complex (representative example: N719) for approximately half a day to have Ru metal complex dyes adsorbed on the surface of the TiO₂ of the porous structure.

As the dye to be adsorbed on the surfaces of the porous titanium dioxide layers 812a and 812b, the same dye (that absorbs light within the same wavelength range) may be used. Moreover, in order to be able to absorb light of a different frequency, a different dye may be adsorbed. For example, a dye that absorbs light of a short wavelength is adsorbed on the first anode electrode layer (812a), and a dye that absorbs light of a long wavelength is adsorbed on the second anode electrode layer (812b). Dyes such as N3 dye, N719 dye and black dye may be used. For example, N719 dye may be adsorbed on the porous titanium dioxide layer 812a, and black dye may be adsorbed on the layer 812b.

Thus, by combining dyes of different light absorption lengths, a solar cell that absorbs a wavelength range broader than one that uses a single dye can be constructed. In the case where a plurality of types of dye are adsorbed on the same titanium dioxide layer, electric current leakage occurs, causing a reduction in photoelectric conversion efficiency. This is assumed to be caused by the different dyes being adjacent. On the other hand, in the present embodiment, dyes of different types are separated from each other, and therefore such a problem does not occur.

Next, the first and second anode electrode layers (810a, 810b) and the first and second cathode electrode layers 814a, 814b are sandwiched between the two transparent substrates 816a and 816b. Then after forming the photo-curing liquid type sealing agent 820 (31X-101 manufactured by ThreeBond Co. Ltd.) around these layers, ultraviolet rays of approximately 3000 mJ/cm2 are irradiated thereon to seal it.

Next, after forming pin holes in portions of the transparent substrates 816a and 816b, the electrolyte 818 containing iodine is injected therethrough to fill the gap between the two electrodes with the electrolyte 818, and then the pin holes are sealed. Subsequently, negative electrode wiring is connected to the metallic meshes 810a and 810b, and positive electrode wiring is connected to the cathode metallic meshes 814a and 814b, to thereby construct the dye-sensitized solar cell.

For the transparent substrates 816a and 816b, a plastic film or the like may be used other than a glass substrate. However, also in this case, an anti-corrosion property for the electrolyte is still required, and an anti-corrosion material is coated on the surface as necessary.

In the dye-sensitized solar cell 800 having the structure described above, the light that has been transmitted through the transparent substrates 816a and 816b is absorbed by the dye adsorbed on the porous titanium dioxide coatings 812a and 812b that construct the anode electrode, and electrons are excited. Since the energy ranking of the conducting zone of titanium dioxide at approximately 0.2 eV is low compared to the ranking for dye excitation, these excited electrons migrate to the titanium dioxide side. Furthermore, these electrons migrate through the anode electrode side electrode meshes 810a and 810b to operate an external load, and then reach the cathode side metallic meshes 814a and 814b. Subsequently, these electrons are given to the electrolyte in a reduction reaction with iodine ions, and then this iodine is diffused, and an oxidization reaction to give electrons to the excited dye occurs. The above cycle is repeated and a photoelectromotive force is thereby generated accompanying steady light irradiation.

In the present invention, since as with the sixth embodiment mentioned above, the transparent substrates 816a and 816b are disposed on both of the upper and lower sides, there is an advantage in that light can be taken from a broad range, and photoelectric conversion efficiency can be improved. Moreover, since overall transparency can be easily ensured, it can be applied to a window section of a building. Furthermore, the transparent substrates 816a and 816b on both sides can be constructed from flexible plastic films, so that a light weight, thin film type solar cell can be constructed easily.

In addition, by adopting the mesh shape for both of the anode electrode and the cathode electrode, the surface area of the dye adsorption coating such as the titanium dioxide coating increases, and the distance between the two electrodes becomes shorter. Therefore a further improvement in photoelectric conversion efficiency can be expected.

The actual way of lacing (weaving) the metallic meshes 810a and 810b is such that they are alternately woven in the vertical and horizontal directions as shown in the enlargement in FIG. 10.

The fine metallic wires and metallic meshes for the anode electrode used in the above respective embodiments may have a structure including at least any one of the highly anticorrosion materials such as tungsten (W), titanium (Ti), and nickel (Ni). In order to enhance the anticorrosion property, a precise titanium oxide (TiO₂) layer may be formed on the surface of the fine metallic wires or the metallic mesh for the anode electrode. Furthermore, in the case where aluminum (Al) is employed, the surface of an aluminum auxiliary electrode is coated with tungsten, titanium, or nickel in order to prevent corrosion of the aluminum caused by the electrolyte (iodine). Since the electrical resistivity of Al is low, a further improvement in photoelectric conversion efficiency per unit area can be expected.

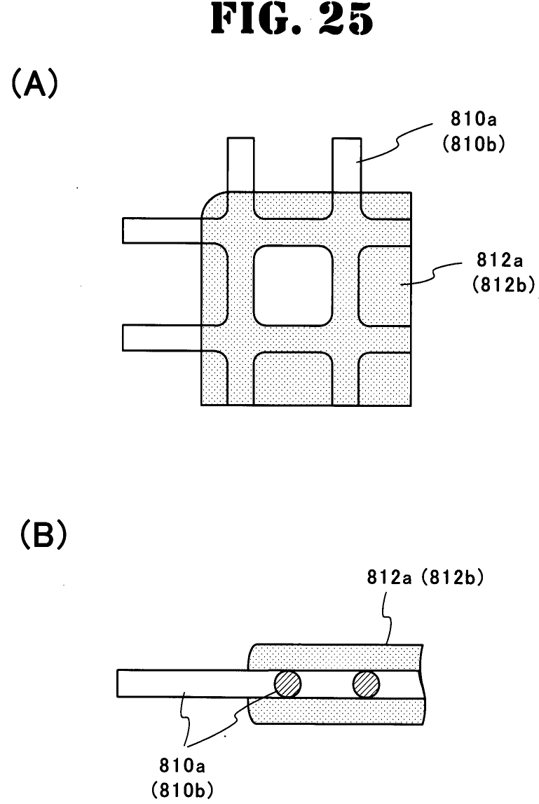

In the case where an aluminum mesh is employed for the anode electrode, then as shown in FIG. 25, a metallic mesh body can be integrally formed by fusing a plurality of fine Al metallic wires disposed intersecting in the lengthwise and crosswise directions (=disposed in a mesh shape).

On the other hand, as the material for the cathode fine metallic wires or the cathode metallic mesh body, for example, Cu, SUS, W, or Al is used, and these materials are coated with platinum (Pt) or carbon (C) that has catalyst properties. In the case of coating with platinum (Pt), first, gold (Au) is plated on the cathode fine metallic wires or the cathode metallic mesh body, and then the gold plated cathode fine metallic wires or the cathode metallic mesh body is coated with platinum (Pt). As a material that has a catalyst property (effect of reducing iodine ions), chloroplatinic acid or PEDOT (polyethylene ethylenedioxythiophene of conductive polymer=Poly(3,4-ethylenedioxythiophene)) may be used.

What is claimed is:

1. A dye-sensitized solar cell comprising a first electrode provided with a photoelectric conversion layer, a second electrode disposed so as to oppose said first electrode, and electrolyte filled at least in between said first electrode and second electrode, wherein
said first electrode has a plurality of first electrode layers disposed superposed in a direction that opposes said second electrode.

2. A dye-sensitized solar cell according to claim 1, wherein at least one of said plurality of first electrode layers has a fine metallic wire set in which a plurality of fine metallic wires are arranged in parallel.

3. A dye-sensitized solar cell according to claim 1, wherein at least one of said plurality of first electrode layers has a construction in which fine metallic wires are formed in a mesh.

4. A dye-sensitized solar cell according to claim 1, wherein said plurality of first electrode layers each have the same form and are disposed in off plane alignment.

5. A dye-sensitized solar cell according to claim 1, wherein said photoelectric conversion layer absorbs light of different wavelengths for each of said plurality of first electrode layers.

6. A dye-sensitized solar cell according to claim 1, wherein a substrate having transmissivity is disposed on said first electrode side, and
said second electrode is disposed on an opposite side of said first electrode to said substrate.

7. A dye-sensitized solar cell according to claim 1, wherein said first electrode and said second electrode are disposed between two substrates having transmissivity.

8. A dye-sensitized solar cell according to claim 7, wherein each of said plurality of first electrode layers is a fine metallic wire set in which a plurality of fine metallic wires are arranged in parallel, and
said second electrode comprises a plurality of fine metallic wire sets disposed in parallel with the fine metallic wire set which constructs said first electrode layer.

9. A dye-sensitized solar cell according to claim 7, wherein each of said plurality of first electrode layers is a fine metallic wire set in which a plurality of fine metallic wires are arranged in parallel, and
said second electrode comprises a plurality of fine metallic wire sets disposed so as to be planewise orthogonal to the fine metallic wire set which constructs said first electrode layer.

10. A dye-sensitized solar cell according to claim 8, wherein said plurality of fine metallic wire sets which construct said second electrode are disposed between two of said first electrode layers.

11. A dye-sensitized solar cell according to claim 9, wherein the plurality of fine metallic wire sets which construct said second electrode are disposed between two of said first electrode layers.

12. A dye-sensitized solar cell according to claim 7, wherein
each of said plurality of first electrode layers comprises fine metallic wires formed in a mesh, and
said second electrode layer comprises fine metallic wires formed in a mesh.

13. A dye-sensitized solar cell according to claim 12, wherein the plurality of fine metallic wire sets which construct said second electrode are disposed between two of said first electrode layers.

14. A dye-sensitized solar cell according to claim 12, wherein
said fine metallic wires which form each of said plurality of first electrode layers are titanium fine metallic wires, and
said fine metallic wires which form said second electrode layer are platinum coated copper wires.
